(19) United States
(12) Patent Application Publication
(10) Pub. No.: US 2009/0193717 A1
(43) Pub. Date: Aug. 6, 2009

(54) OPERATOR SYSTEM FOR AN APERTURE MEMBER

(75) Inventors: Ulrik Vagn Ebbe, Greve (DK); Bjarne Ravndal Andreasen, Struer (DK); Niels Peter Jepsen, Struer (DK); Didier Claude Rene Corniere, Villenave d'Ornon (FR)

Correspondence Address: CANTOR COLBURN, LLP, 20 Church Street, 22nd Floor, Hartford, CT, 06103, US

(73) Assignee: VKR HOLDINGS A/S, Horsholm (DK)

(21) Appl. No.: 12/412,940

(22) Filed: Mar. 27, 2009

Related U.S. Application Data
(63) Continuation of application No. 10/494,462, filed on Sep. 20, 2004.

(30) Foreign Application Priority Data
Nov. 14, 2001 (DK) PA 2001 01694

(51) Int. Cl. E05F 15/00; A44B 13/00; H01L 31/04; G08B 5/22; G08B 5/00; H02J 7/00

(52) U.S. Cl. 49/324; 24/592.1; 136/252; 340/815.45; 340/815.4; 320/101; 340/825.69

(57) ABSTRACT

An operator system for an aperture member, such as a window or a door, having a fixed frame and a movable element such as a movable sash, the operator system being designed for operating the movable elements associated with the aperture member, e.g. for opening and closing of the aperture, and the aperture member having such operator system.

### CROSS REFERENCE OF APPLICATIONS

This application is a continuation application of U.S. patent application Ser. No. 10/494,462, filed on Sep. 20, 2004, which claims priority to PCT Application No. PCT/DK02/00761, filed on Nov. 14, 2002, and all the benefits accruing therefrom under 35 U.S.C. § 119, the contents of which in their entirety are herein incorporated by reference.

### FIELD OF THE INVENTION

The invention relates to an operator system for an aperture member, such as a window or a door, having a fixed frame and movable means such as a movable sash, the operator system being designed for operating the movable means associated with the aperture member, e.g. for opening and closing of the aperture, and an aperture member, such as a window or a door, having a fixed frame and movable means such as a movable sash, the aperture member comprising an operator system for operating the movable means associated with the aperture member, e.g. for opening and closing of the aperture.

### BACKGROUND OF THE INVENTION

Power operating means for windows and similar component are known in a wide variety of embodiments.

Examples of such prior art operating means are described in e.g. GB 2 239 896 A, U.S. Pat. No. 5,006,766 A, U.S. Pat. No. 5,313,737 A, U.S. Pat. No. 5,355,059 A, U.S. Pat. No. 5,449,987 A and U.S. Pat. No. 5,813,171. However, all of these prior art operating means are designed for installation in windows etc. in connection with the actual installation of the windows or as retrofitting. Thus, the actual installation of such operating means is associated with considerable effort, e.g. in order to install the driving means in the windows, arrange the power supply, arrange the control means, set up the system(s) etc.

The above-mentioned U.S. Pat. No. 5,813,171 A describes an assembly for opening and closing a window sash from and against a window frame: This assembly comprises a housing containing an electric motor, drive train, gear mechanism and clutch mechanism. Further, the assembly comprises an operator arm for opening or closing the window. The housing is accommodated in a cavity of the sash, and power and control lines to the motor extend from the motor to the jamb, for example along the operator arm. The power supply and control arrangement is not described in detail, but apparently these must be installed specially and facilities for remote control are apparently not included. This prior art operator system may be integrated into the design of the window, e.g., at the time of manufacture, and retrofitting is also possible. However, fitting the operator and especially the housing into the window will require special skills, e.g. for making the cavity in the sash, for installing power and control lines etc. In the description it is mentioned, though, that retrofitting may be easily accomplished by installing a new sash incorporating the operator housing, thereby discarding the old sash. Thus, the fitting of this prior art system will be labour intensive and—especially if a new sash is to be purchased and installed—relatively expensive.

WO99/32748 AI describes a drive system for a revolving door. This system comprises an electromechanical drive unit incorporating a drive motor, a transmission and a load transmitting unit. This drive unit is together with a power supply, a receiver for control signals and a control unit accommodated in a cavity in the door leaf. This prior art drive system is particularly designed for revolving doors and is not intended for installation in ordinarily used windows, doors etc. Further, the installation of this prior art system requires that a cavity is available or is made in the leaf of the door, and power lines must be installed, e.g. from the power supply in the cavity to a mains power line in the building. Thus, the fitting of this prior art system will be limited to revolving doors, relatively labour intensive, and relatively expensive.

It has been realised that there is a need for an operating system that may be installed and in particular made operational without having to use unnecessary effort, resources etc. In particular, it has been realised that there is a pressing need for an operating system that may be installed during or in immediate connection with the manufacture of the window, the door etc. in question.

Also, it has been realised that there is a need for an operating system that may be delivered to a customer as one unit together with the window the door etc., and that such a unit may be made operational with only a few labour operations on the part of the customer.

### SUMMARY OF THE INVENTION

The invention relates to an operator system for an aperture member, such as a window or a door, comprising a fixed frame and movable means such as a movable sash, the operator system being designed for operating the movable means associated with the aperture member, e.g. for opening and closing of the aperture, and the operator system comprising means for power supply, control signal supply means and an operator having drive means. According to the invention, the means for power supply comprises a power supply module and the system further comprises a connection module and receiver means for facilitating reception of control signals from control means, the operator and the power supply module being connected to the connection module and the receiver means or a connecting interface for said receiver means being incorporated in the operator system in such a manner that control signals may be transmitted to the operator.

A system of components for an operator system is provided in which said components are being laid out in a modular approach and prepared for interconnection in a manner allowing the components to be installed in an aperture member during manufacture of the member or at least prior to installation of the member in an aperture of, e.g., a building. Thus, the operator, the power supply module and the connection module may readily be installed in or on the frame of the aperture member together with the necessary wiring etc. Further, necessary modifications of the frame in order to be able to install the components and the wiring may advantageously be made at this stage, e.g., in workshop or factory facilities. This will result in an aperture member, e.g., a window or a door, which will in reality be ready for operation immediately upon installation in, e.g., a wall, and possibly after the power supply means have been plugged into a power outlet, batteries have been inserted in a remote control and/or a receiver module has been inserted in an adaptor/interface unit.

Further, such a system may also be provided as a retrofitting kit, e.g. a kit comprising all necessary components for fitting into an already installed door or a window that has been designed to accommodate, e.g., a power operator. These components are designed to be easily installed in or on the window or door in question, and wiring etc. are easily installed and connected to the components due to the ready-to-connect configuration and the connection module. Hereafter, only the plugging-in of the power supply cord in a mains outlet or the insertion of, e.g., batteries need to be done, before the system is operational.

Further, a system according to the invention is designed in a manner allowing for numerous modifications and embodiments. This is accomplished via the connection module, which allows modular interconnection of the necessary components and further facilitates the addition of other modules/components, e.g., by having a number of additional terminals, whereby a flexible system is achieved. It is particularly noted that the addition of further modules or components may be performed without having to install an extra power supply (or supplies) and without having to provide a further control system. An additional module, e.g., for driving a roller blind may thus be driven by the same power supply as the, e.g., window operator, and even the same control means, e.g., a remote control, may be used, since the power supply of the system according to the invention may be designed to supply power to a predefined number, e.g. two, three or more, of modules and since the system may be designed to perform control of such a predefined number, e.g. two, three or more, of modules.

As specified the operator system may be utilized for opening and closing, e.g., a door or a window, or may be utilized for driving other means associated with, e.g., a door or a window. Such associated means may, for example, be screening devices in numerous forms, awnings, curtains, roller blinds, shutters etc. According to an embodiment, the receiver means may be designed as a receiver module connected to the connection module, which is designed to transmit control signals to the operator.

The receiver module may be installed in or on the frame and connected to the connection module at the production stage and no further steps, apart from coding etc., need to be performed in relation to the reception of control signals when preparing the operator system for use, e.g., when the window is installed. Further, the system makes its possible to place the receiver module in a position in which signals from a remote control will not be obstructed, e.g. by material of the frame, etc. This is especially advantageous in relation to remote control systems utilizing radiation, which is easily moderated by solid matter, e.g. infrared radiation. Thus, the receiver may be placed in the interior of the building such as, for example, at the side of the frame facing into a building, associated with or integrated with light switching fixture etc. while the operator, the connection module etc. may be placed at a convenient location, e.g. at a frame part facing the movable member, which is usually situated at the side of the frame facing the exterior or the outside of the building.

According to another embodiment, the connecting interface for the receiver means may be connected to the connection module, which is designed to transmit control signals to the operator.

The connecting interface for the receiver means may be installed in or on the frame and connected to the connection module at the production stage and only the insertion of a separate receiver module in the connecting interface must be performed in relation to the reception of control signals when preparing the operator system for use, e.g., when the window, for example, is installed.

According to a further embodiment, the receiver means or a connecting interface for the receiver means may be comprised in the housing means of the operator.

Thus, an advantageous embodiment is achieved in which the number of separate components has been reduced and the layout simplified. Further, the need to modify the frame in order to accommodate wiring from the connection module to the receiver means and possible modifications of the frame in order to accommodate the receiver module or the connecting interface have been avoided.

The parts of the operator system may be designed for installation in or on a fixed frame for or on or in means associated with an aperture member such as a door or a window prior to installation of the aperture member in an aperture and the necessary wiring for the power supply and/or for communication may also be installed and connected prior to installation of the aperture member in an aperture.

Such aperture members may, e.g., be delivered to a building site completely fitted with all necessary elements in order to be fully operational, apart from such parts as a remote control and/or a receiver module, which must be inserted in connection with the initial set-up of the system. However, such parts may be delivered together with the window or door. It will be understood that an operator designed for power operation may be provided as an integrated part of a manually operated opening/closing means, whereby a window, for example, may be delivered and installed as a manually operated window, but in fact comprising means allowing a relatively simple installation of the remaining necessary parts, whereby the manually operated window is turned into a power operated window. Thereby, windows or doors may be delivered as standard units comprising the essentially necessary parts for power operation. However, they may be operated manually in usual manner, and if power operation is required, this may be achieved relatively simple, e.g. by adding a receiver module, batteries or by plugging a power supply cord into a normally available domestic power supply outlet. Thus, such a window or door may be installed in a building and configured as a power operated window or door at the time of installation, or the window or door may be turned into a power operated window or door later on in dependence upon the requirements and needs of the residents.

Further, the operator system may comprise a sensor module, e.g., a rain or humidity sensor module, an intrusion sensor, a light intensity sensor, an obstruction sensor etc. connectable to the connection module of the system and pre-mountable and pre-connectable. For instance, the operator system may be provided with means for ensuring that, e.g., an open window will be closed automatically when it starts to rain or/and that certain safety and/or security operations will be performed when a certain incident has occurred in a simple and efficient manner. The addition of such a sensor module may be performed in advance of the installation of the e.g. window, or it may just as easily be done afterwards.

According to a further embodiment, the operator system may comprise two or more operators connected to the connection module of the system.

Specifically, further operator modules may readily be included in the system, e.g. operators for window blinds, roller blinds, curtains, blackout curtains, awnings etc. These further operators will be provided by means of the power supply via the power supply wiring and the connection box module. Control signals for such further operators may be delivered from a common receiver module via the connection module or from a receiver comprised in the operator, if the system is of the type having receivers built into the individual operators. The addition of such further operators may be performed in advance of the installation of the e.g. window, or it may be done afterwards. Further, such further operators may, according to this embodiment of the invention, be supplied with electrical power via the power supply module already comprised in the system, whereby the need to install separate power supply means is avoided. The power supply module already comprised in the system may be designed for supplying power to a number of modules, e.g. have a rating corresponding to two, three, four or more modules.

The power supply module of the system may be designed for connection to a mains power supply, e.g. a 230 V AC power supply. Specifically, the power supply may be established in an efficient and simple manner, e.g. by plugging the cable from the aperture member into an outlet of a domestic electric mains system or by connecting this cable to a junction or distribution box. Hereby, the problems associated with prior art systems, e.g. installation of dedicated power supply systems such as a low voltage DC-system, will be avoided, and authorized persons such as electricians need not be involved since only simple plugging is required.

According to a further embodiment, the power supply module of the system may comprise power storage means, e.g. in the form of a battery or batteries, and charging means may be provided. Accordingly, a number of advantages is achieved. The power storage means may serve as a buffer in order to deliver necessary power surges, e.g. when power to an operator motor is switched on. Further or instead, the power storage means may serve as a power back-up system providing power for continued operation of the, e.g., window during power failure.

In a further embodiment the charging means may be supplied from a mains power supply, from a solar cell power supply and/or from another power supply. Specifically, a flexible power supply may be provided, which has been tailored to the particular needs of the consumer in question.

A solar cell power supply may be particularly advantageous when used in connection with a system having an operator placed in means arranged movably in relation to a fixed part of the aperture member, for example, an operator placed in a part of a roller blind intended for being lifted and lowered in relation to the window frame. A supply of power via wires from, e.g., a mains supply via the fixed part may be difficult to establish and may prove to be disadvantageous in practice in such cases. Instead or in addition, a solar cell may be arranged on the movable part in order to provide electric power, and further a rechargeable battery or batteries may be provided in the same part in order to ensure a sufficient power supply, i.e. by storing energy.

The control means of the operator system may be a portable remote control designed to communicate via electromagnetic radiation, e.g., infra red radiation, radio frequency radiation etc., whereby a user may control the opening/closing of the movable aperture member and/or possibly further operators driving curtains etc. in a convenient manner. Further, two or more operators pertaining to separate apertures may advantageously be controlled by using one single remote control.

In a further embodiment the receiver means for facilitating reception of control signals may be arranged as transceiver means and said control means may correspondingly comprise transceiver means. Thus, two-way communication may be established between the transceiver means associated with the aperture member and the control means and/or transceiver means associated with another aperture member. The control means may receive information from the transceiver means associated with the aperture member concerning the state of the transceiver means and/or operator, e.g. ready for operation, busy, non-operational, operation ended etc. and further the transceiver means may communicate with transceiver means associated with another aperture member, e.g. in order tore-transmit a received control signal intended for the other aperture member etc. Further, by this embodiment additional features may be facilitated, e.g. in connection with configuration schemes etc. involving communication of codes, addresses etc. between a remote control and one or more controlled means.

The invention also relates to an aperture member such as a window or a door comprising a fixed frame and movable means such as a movable sash, the aperture member comprising an operator system for operating the movable means associated with the aperture member, e.g. for opening and closing the aperture.

Hereby, such aperture members may be delivered to, e.g., a building site completely fitted with all necessary elements in order to be fully operational apart from such parts as a remote control and/or a receiver module, which must be inserted in connection with the initial set-up of the system. However, such parts may, e.g., be delivered together with the window or door. Hereby, a “plug and play”-system is achieved for remote-controlled windows, doors etc.

It will further be understood that an operator designed for power operation may be provided as an integrated part of a manually operated opening/closing means, whereby a window, for example, may be delivered and installed as a manually operated window, but in fact comprising means allowing a relatively simple installation of the remaining necessary parts, whereby the manually operated window is turned into a power operated window. Thereby, windows or doors may be delivered as standard units comprising the essentially necessary parts for power operation. However, they may be operated manually in usual manner, and if power operation is required, this may be achieved relatively simple, e.g. by adding a receiver module, batteries or by plugging a power supply cord into a normally available domestic power supply outlet. Thus, such a window or door may be installed in a building and configured as a power operated window or door at the time of installation, or the window or door may be turned into a power operated window or door later, depending on the requirements and needs of the residents.

The aperture member may be a combination of all components necessary for operation, e.g. an operator, a power module, a connection module, receiver means and control means.

According to a further embodiment, the aperture member may comprise means for establishing communication to receiver means, preferably in the form of a connecting interface, provided in or on part of the aperture member and designed to accommodate the receiver means, and/or corresponding communication lines.

Accordingly, the receiver may conveniently be placed appropriately in the aperture member, e.g., after the aperture member has been installed in a building. Further, a receiver module may be set up to correspond to a specific remote control, e.g., a coding may be performed of the receiver module and/or the remote control, via e.g., DIP-switches, before the receiver module is placed in the connecting interface. Thereby, the receiver may be coded to communicate with the remote control delivered together with the aperture member, or the receiver module may be coded to respond to a remote control already present, e.g. a remote control used for controlling e.g. windows already installed. Instead, the receiver may be set up to correspond to a specific remote control, e.g. a coding may be performed of the receiver module and/or the remote control, after being placed in the interface, e.g. by wireless configuration schemes etc.

According to another embodiment, the operator system may be arranged with control and receiver means designed to communicate mutually by means of infrared signals, whereby a remote control system specifically designed for use in connection with an aperture member having a receiver module placed in or at a front part e.g. a part facing toward the user, is provided.

Alternatively, the operator system may be arranged with control and receiver means designed for mutual communication via radio frequency signals, whereby a remote control system specifically designed for use in connection with an aperture member having a receiver module placed in the interior of the aperture member, e.g., in the housing of the operator or the like, is provided.

The movable means may include a movable sash, whereby an aperture member having means for achieving an automatic opening or closing of the movable sash or an automatic adjustment of the position of the movable sash may be provided.

In a further embodiment, the movable means may include a screening device, e.g. window blinds, roller blinds, curtains, blackout curtains, awnings etc., whereby an aperture member having means for achieving an automatic activation of the movable means and/or an automatic adjustment of the position of the movable means may be provided.

### BRIEF DESCRIPTION OF THE DRAWINGS

The foregoing aspects and advantages of the present invention will be described in further detail below with reference to the drawings of which:

FIG. 1 is a block diagram of a system according to an embodiment of the invention,

FIG. 2 is a block diagram of a modified system according to a second embodiment of the invention,

FIG. 3 is an operating system and some of its components according to an aspect of the invention in combination with a closing member such as a window,

FIG. 4 is an interior perspective view of a window frame according to an embodiment of the invention,

FIG. 5 is a schematic view of components of the operator system according to a further embodiment of the invention,

FIG. 6 is a window with a screening device having an operator system according to an embodiment of the invention, and

FIG. 7 is an elevational view of elements in a bottom roller of the screening device as in FIG. 6.

### DETAILED DESCRIPTION OF THE INVENTION

Detailed reference will now be made to the drawings in which examples embodying the present invention are shown. The drawings and the detailed description provide a full and detailed written description of the invention, and of the manner and process of making and using it, so as to enable one skilled in the art to make and use it, as well as the best mode of carrying out the invention. However, the examples set forth in the drawings and detailed description are provided by way of explanation only and are not meant as limitations of the invention. Thus, the present invention includes any modifications and variations of the following examples as come within the scope of the appended claims and their equivalents.

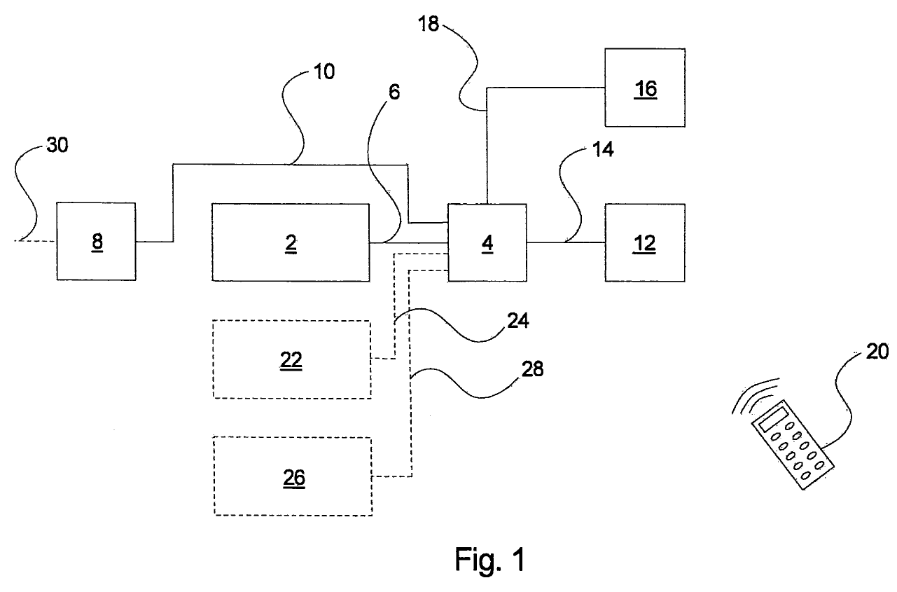

FIG. 1 shows a block diagram of an integrated control or opening system for a window, a door, a closure, an aperture member or a similar component of a building etc. according to an embodiment of the invention.

An operator, e.g., a window or a door operator or an operator for means associated with, e.g., a window or a door, is generally designated 2 and comprises power drive means, e.g., an electric motor, for opening and closing of a wing, e.g., a closing member, a window or a door or for driving means such as a screening device associated with a window or a door. The operator 2 is connected via electric wires 6 to a connection box 4, which serves as central control means for the illustrated system. The connection box 4 is also connected to a power supply 8 via power supply wiring 10.

The power supply 8 may be designed in numerous manners as it will be evident to a skilled person. For example, it may be in the form of an electric transformer supplied with electric power via power lines 30 from a common power distribution system, e.g. a 230V 50 Hz or a 110V 60 Hz mains system. The power supply 8 may also incorporate rectifier means, filtering means, power stabilizing means or other commonly used power processing means and circuits.

However, the power supply 8, may also incorporate power storage means, e.g. large capacitors, batteries etc. These power storage means may serve as power supply to a system according to the invention independently of other electric supply sources, or may serve as means of providing sufficient power in situations demanding peak power, e.g. power surges during initial movement of a window, for example, or closing of a window when a movable window sash is drawn firmly towards a fixed window frame before the operator is stopped. In such situations, the power storage means, e.g. a capacitor, a battery or batteries, may serve as buffer by which other elements of the system, e.g., a transformer included in the power supply 8, may be designed with rated specifications, e.g. rated current, lower than e.g. the peak currents necessary for driving the operator.

If batteries are used, these may be in the form of rechargeable batteries or in the form of primary battery cells, e.g. non-rechargeable batteries. If rechargeable batteries are used, charging of these may be provided by commonly known charging circuits, e.g. connected to AC mains supply 30. Suitable alternatives such as solar cells situated on the front part of, e.g., a window or a door frame may also be used.

When power storage means such as a battery or batteries are included in the system, this may further serve as a power back-up system in case of power failure.

Also shown in FIG. 1, a receiver module 12 is connected to the connection box 4 by a communication line 14, e.g. a wire communication.

Further, other specific modules of significance to the functionality of the control system, e.g. the window operator, may be connected to the connection box 4. For example, a sensor module 16, e.g., a rain sensor module, may be connected to the connection box 4 by wire means 18 as illustrated in order to achieve automatic closing of, e.g., an open window under certain circumstances, for example when a certain level of moisture is detected by the rain sensor 16. Other examples of such further modules which may be connected to the system may be temperature sensors, wind sensors, e.g. comprising an anemometer, motion detectors, intrusion detectors, glass break detectors, obstruction detectors or other forms of safety detectors etc.

As indicated in FIG. 1, a connection box 4 according to the invention may also be connected to further operator modules, e.g. 22 and 26, by communication means 24 and 28, respectively, in order to control such operator modules as well. These further operator modules may be, e.g., operators of window blinds, roller blinds, curtains, blackout curtains, awnings etc. and will be provided with the power supply via the power supply wiring 10 from the power supply 8 and via the connection box 4.

The operator 2, e.g. the “main” operator placed on or in e.g. a window may be arranged for driving e.g. a screening device instead of being arranged for opening and closing of a window. In this case a further operator module may be arranged for opening and closing the window, and said further operator may be installed later on in addition to the main operator already installed, as explained above, and in accordance with the particular needs of the customer.

An operator system according to the invention will be controlled by signals received by the receiver module 12. These signals may be delivered to the receiver module by electrical wires, light guides or as shown, via a remote control 20. This remote control may operate via wireless signals selected from a wide range, e.g. electromagnetic radiation signals in the form of, for example, infrared signals, radio frequency signals etc.

In the embodiment shown in FIG. 1 with the receiver module 12 designed as a separate unit, infrared signals as well as radio frequency signals may readily be utilized.

It will be understood that the receiver module 12 may be designed as a transceiver module and that the control means 20, e.g. a remote control, may also be arranged with transceiver means. In this case the receiver/transceiver module 12 may be able to perform a two-way communication with the control means 20 and/or with other receiver/transceiver modules placed in further e.g. windows or doors. Hereby the receiver/transceiver module may be able to transmit e.g. confirmation signals, signals indicating a state, e.g. busy, operating, error etc., of the receiver/transceiver module to the control means 20, or may be able to communicate with other receiver/transceiver modules, e.g. in order to retransmit received control signals to these modules.

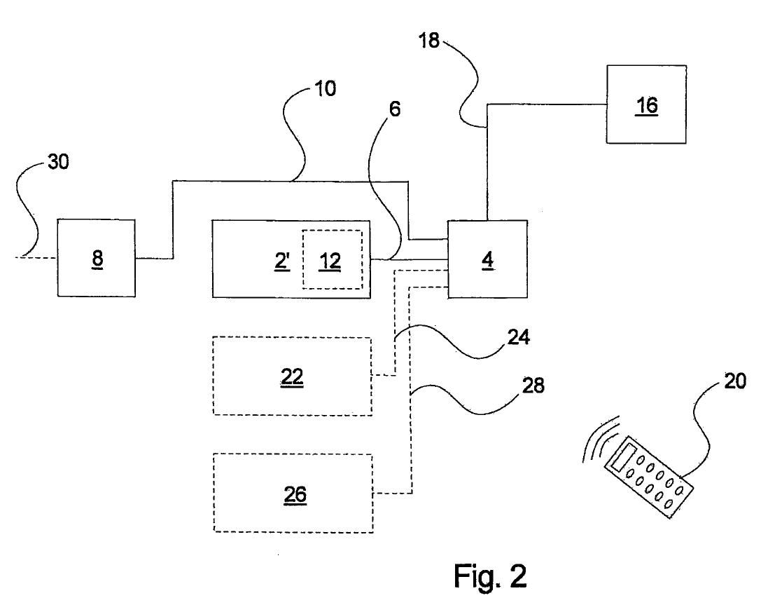

A slightly modified embodiment which has been specifically designed for use in connection with a radio frequency control system will be described with reference to FIG. 2.

This embodiment essentially comprises the same components as specified above. However, the receiver module 12 has been included in the operator, now generally designated 2′, or rather in a housing containing the drive means, electric motor, gearing means, etc. In this aspect of the invention, a compact construction is achieved and control signals from the receiver module 12 can be led directly to the operator. The same will be the case with further operators 22 and 26, if these are present in a specific system according to this embodiment.

However, as it will be evident to a skilled person and as explained in further detail below, this embodiment will put constraints on the selection of control radiation signals utilized for controlling the system, e.g. the type of radiation signals emitted by the remote control 20. In essence, since signals radiated by the remote control 20 have to pass some sort of shielding, e.g. a material used for the housing of the operator 2′, or a material used for window or door frames etc., signals which cannot pass such material or which will be dampened significantly, e.g. infra red signals, will not be of practical use in relation to this embodiment. Radio frequency signals will, however, not be dampened or impaired, at least not significantly, when used under these circumstances and the shielding provided by the materials in question will be of no or only minor significance.

The receiver means 12 and the control means 20 utilized in this embodiment may be designed as transceivers in analogy with what has been explained above in relation to the embodiment shown in FIG. 1.

The connection box module 4 may also be placed in connection with or even integrated with the operator module 2.

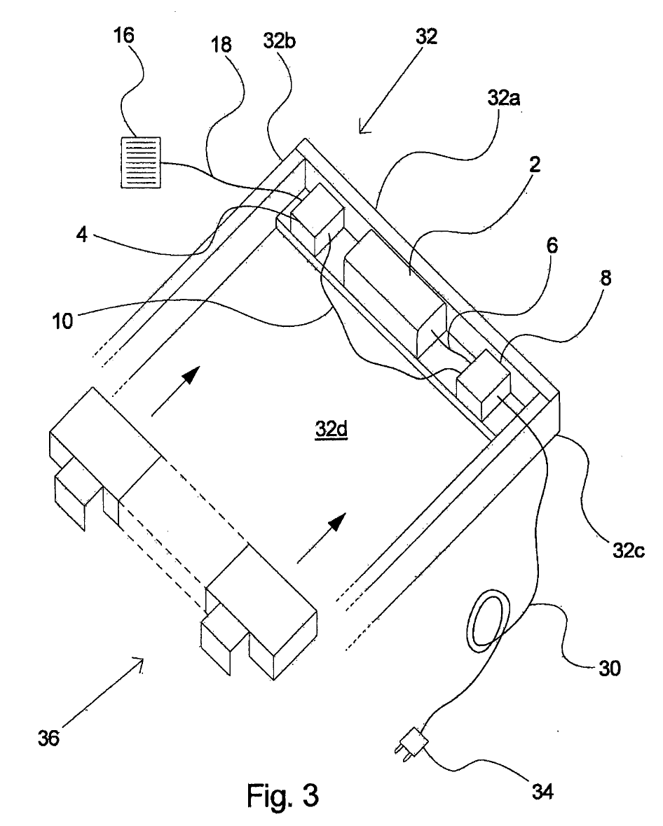

Installation of an operator system according to the invention will now be described in the following with reference to FIG. 3. In this figure, the installation is illustrated in relation to a closing member such as a window, e.g. a roof window. This window, of which only the upper part is illustrated, comprises a fixed frame having an upper frame part 32a and side frame parts 32b and 32c. A movable, e.g. a pivotal sash holding a transparent part such as a glass plate, for example, will normally cover or close the opening 32d defined by the fixed frame 32, but for reasons of clarity, such a sash has not been illustrated in FIG. 3. It will be understood that such a sash may be mounted in a number of ways, e.g. hinged at the bottom, hinged at a middle part, hinged to pivot in relation to a vertical axis etc. However, in the following, it will be understood that the window shown in FIG. 3 is designed to accommodate a sash which may be movable in relation to a horizontal axis and that an upper part of such a sash may be pulled towards the upper frame part 32a in order to close the window and may be pushed away from this frame part in order to open the window to a certain degree, adjustably controlled by the user. It will thus be understood that the window frame in FIG. 3 is seen from the side of the window normally facing the outside.

The illustrated components of an operator system according to the invention shown in FIG. 3 are mounted when the window is manufactured or at least prior to the purchase by the customer and the installation of the window in a house, a building etc.

The operator 2 (or 2′), the power supply module 8 and the connection box module 4, which are illustrated in a schematic manner, are mounted by any suitable attachment devices such as screws in the upper part of the frame 32 and with the operator 2 (or 2′) facing towards the movable window sash. It will be understood that the operator 2 (or 2′) is provided by an operating or linkage member (not shown) connected to the movable window sash in order to open/close this. This operating member may be a flexible operating member designed as a chain or a chain-like member as described e.g. in EP 0 624 703 B1. Further, the operator 2 (or 2′) may be of a type or similar to the type disclosed in EP 0 624 703B1, although other types of operators may also be utilized in connection with the present invention, e.g. operators for driving screening devices, curtains, awnings etc. associated with e.g. a window or a door.

After having mounted the operator 2 (or 2′), the power supply module 8 15 and the connection box module 4, the corresponding wires and/or communication lines 10, 6 and 30 are connected to the respective components and may be secured to the window frame parts. The mains power supply 30, which is provided with a regular mains plug 34 but may of course be connected to the mains supply in any other suitable manner, may have to pass a frame part, e.g. a side frame part 32c or a top or bottom frame part of the window frame. Therefore, a groove, a through hole or the like (not shown) may be made in the window frame in order to accommodate the power supply cable 30.

It will be understood that all wires, cables, communication lines etc. used in connection with a system according to the invention may be supplied with plug connectors or other similar means in order to establish the necessary connections to/from the components in an advantageous manner. Of course, other electric fastening means such as terminal screws placed on the components may also be used to establish the electric connections.

Further, the sensor module 16, e.g. a rain sensor module, is connected to the connection box module 4 via the wire 18, which is provided with a plug (not shown) to facilitate the connection. The sensor module 16 is mounted in accordance with the requirements of the particular type of sensor, e.g. in case of a rain sensor module mounted on a suitable spot of the fixed window frame 32 or possibly on the movable window sash. Special provisions for accommodating the wire 18, e.g. a groove, a notch etc. may be provided in the frame 32.

A receiver module 12 is not shown in FIG. 3. If the operator 2 is of the type including a receiver module, e.g. an operator 2′, the receiver means will naturally be in the housing of the operator. However, if the operator 2 is not of the type including a receiver module, it will be understood that this receiver module 12 will be located on the other side of the window, e.g. the side normally inside a house or a building, since control signals from e.g. a remote control 20 will normally be received from this side.

Thus, the fixed window frame will have to be modified on this side to accommodate the receiver 12, e.g. a recess or the like, must be made in the frame. Correspondingly, a hole or the like must be made in order to guide the communication line 14 from the connection box module 4 to the inside of the window. Further, instead of mounting the receiver module 12 in the window frame, a connecting interface connected to the communication line 14 may be mounted. This embodiment will be described in further detail below.

Finally, shielding means 36 are mounted at the upper frame part 32a, covering the connection box module 4, the power supply 8 and the associated wiring etc. whereby the appearance of the window frame part will be uncluttered and neat and whereby the wiring etc. will not unintentionally be separated from the modules etc.

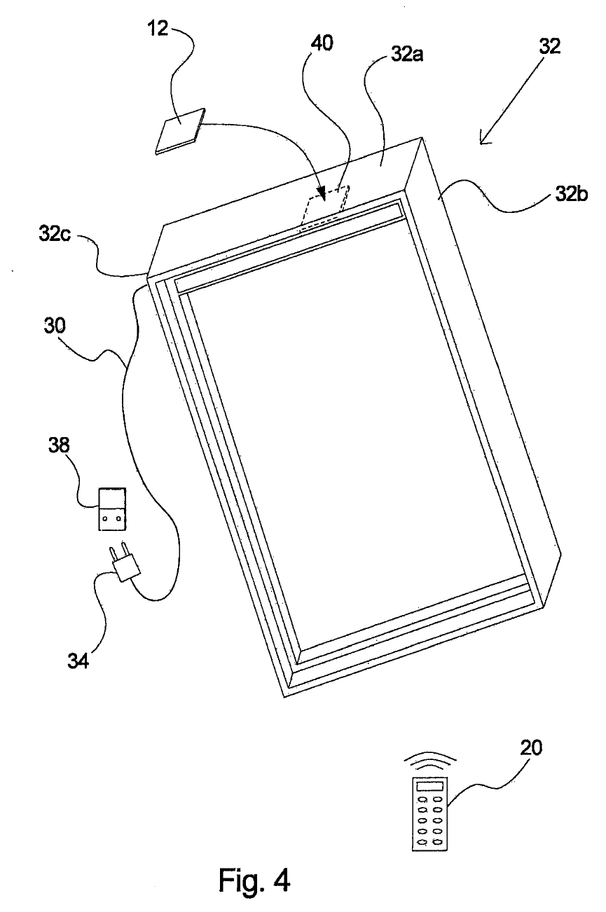

FIG. 4 illustrates a window frame, e.g. a roof window frame, generally designated 32 and shown in perspective from the inside. The window frame is provided with components of an operator system as described above in connection with FIG. 3. These components are not visible in FIG. 4 apart from the power supply cable 30 with the plug 34, which may be readily plugged into a mains outlet 38 as indicated. However, a connecting interface 40 is indicated in the figure and placed in the upper frame part 32a of the window frame 32 in a recess or the like provided in the frame. It will be understood that such a connecting interface 40 comprises connectors for providing electric connections to a receiver module 12. These connectors (not shown) are connected to the communication line 14 which provides communication to the connection box module 4.

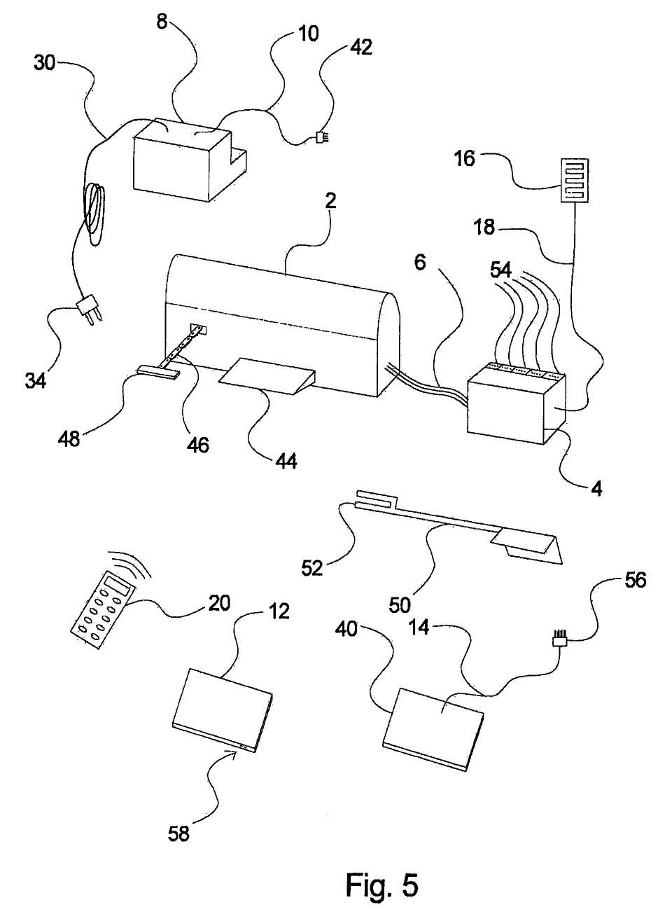

As shown in FIG. 5, a receiver module 12 may readily be inserted or plugged into the connecting interface 40, after which an operator system according to the invention will in principle be ready for operation.

More specifically, FIG. 5 illustrates the components in the operator system schematically according to an embodiment of the invention prior to mounting of these (or some of these) in/on a window, a door or the like in accordance with the invention.

Starting at the upper left corner of FIG. 5, the power supply module 8 is illustrated with its mains power supply cable 30 having a plug 34. Further, the power supply wire 10 is shown and, as indicated, may also be provided with an end plug 42 for plugging into a corresponding connector 54 on the connection box module 4.

The operator 2 is shown with an operating or linkage member 46 in the form of a chain-like member having end fastening means 48 for connection of the chain-like member 46 to a movable part of a window or a door, e.g. to an upper sash part. The fastening means 48 may be connected to a sash part via a furnishing or bracket 50 having a fork part 52. This fork part 52 may grip the end fastening means 48, which may potentially be introduced in a recess in a sash part, and the furnishing 50 may then be secured, e.g. via screws to the sash part.

The operator 2, which may also have the schematically shown means 44 for securing it to the fixed window frame part 32a, may be of the type described in EP 0 624 703B1 or of a similar type as stated above. As indicated, a wire connection 6 is established between the operator 2 and the connection box module 4, possibly via a plug-connection (not shown). It will be understood that an operator for driving a screening device, an awning, curtains etc. may be used instead of or in addition to a type for opening and closing, e.g., a window.

The connection box module 4 is also, as described above, connected to the sensor module 16, e.g., the rain sensor module by wire means, possibly also via a plug-connection (not shown). Finally, the connection box module 4 comprises a number of plug connectors 54, which may be male or female connectors. These serve to establish a connection to the operator 2 as described above or to establish a connection to further operators 22 and 26 etc. Further, such plug connectors 54 may also serve to establish a connection to other modules, e.g. the power supply module 8, the rain sensor module 16, the receiver module 12 or the connection interface 40 for this, and possibly other modules such as temperature control modules, intrusion detector modules, safety detector modules etc.

Finally, in FIG. 5 the remote control 20 and the receiver or transceiver module 12 intended for insertion in the connection interface 40 are illustrated. The connection interface 40 will be connected to the connection box module 4 via a communication line 14 as explained above, which is provided with a plug 56 for cooperation with one of the plug connectors 54. The receiver/transceiver module 12 is provided with one or more indicators 58, e.g. LEDs or other suitable indicators. The indicator(s) may serve to indicate to a user, e.g. by flashing, that a control signal from the remote control has been received, and by, e.g., constant light that an operator is active, i.e. that the drive engine is running.

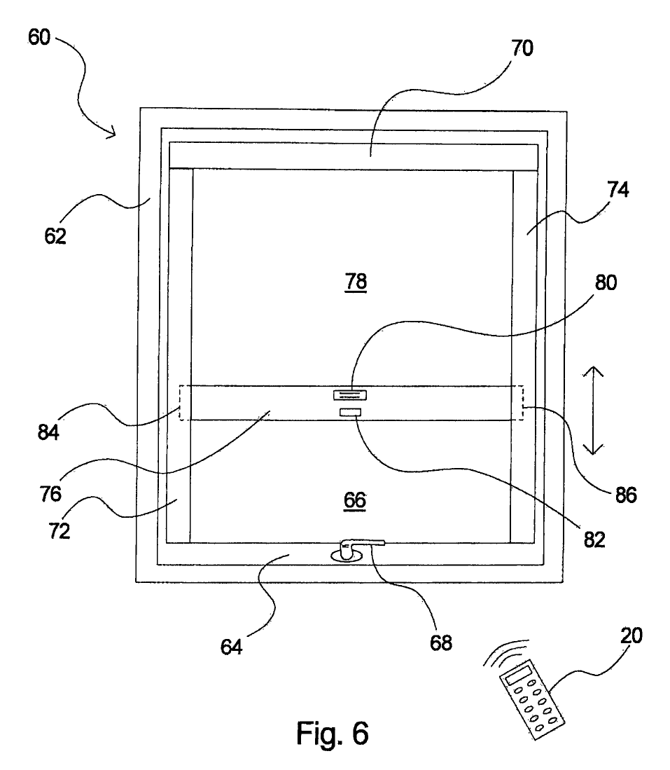

FIG. 6 illustrates an operating system according to the invention in combination with a screening device for an aperture member such as a window generally referred to as 60. The window 60 is seen from the inside and said window is provided with a light screening device driven by a system according to an embodiment of the invention.

The window 60 comprises a frame 62 carrying a sash 64. This sash 64 comprises a glass pane 66, and if it is intended to be opened, the frame 62 and the sash 64 will also feature means for opening hereof such as hinges and as illustrated a closing handle 68 or power driving means (not shown) in the form of an operator for opening and closing the window.

At the top of the window 60, a top box 70 has been mounted on or in the frame and rails 72 and 74, respectively, have been mounted or shaped in the side sections of the sash 64. These rails 72, 74 have been designed in a manner to serve as guides for a bottom roller 76, which may be moved up and down as illustrated by the double-headed arrow between the lower edge of the window and the top box 70 and to any given position in between these limits.

The bottom roller 76 is connected to a screening device or the like, 78, which extends between the bottom roller 76 and the top box 70. This screening device may be designed in a number of ways, such as e.g. a pleat canvas, but it may also involve a canvas as illustrated to be wound up on a spring-based roller (not shown) placed in the bottom roller 76 or in the top box 70.

The screening device 78 may be designed in various materials and may have various properties depending on its specific purpose, e.g. as a light screening device from e.g. incoming sun light. Thus, the canvas may be completely transparent but have a light-filtrating effect or it may be a canvas with less or more screening properties, i.e. any given degree of transparency, potentially chosen according to particular light spectrums or the canvas may serve to completely shut out any incoming light, such as a blackout curtain.

As mentioned, the rails 72 and 74 are designed in such a manner that they may guide the bottom roller 76 during movement and for this purpose, the bottom roller has been provided with means at both ends, 84 and 86 respectively, for cooperation with the rails 72 and 74 which includes the transfer of traction power between the bottom roller 76 and the rails 72 and 74.

The bottom roller 76 further comprises means for operating the bottom roller 76, the operating means being controllable via e.g. wirelessly transferred signals, e.g. from a remote control 90, the signals being intercepted by a receiver or transceiver 82, e.g. a receiver or a transceiver of infrared or RF signals, the receiver or transceiver 82 being located, e.g., at front of the bottom roller 76 as shown. Also, this may be provided with an operating grip 80 for manual control of the screening device 78.

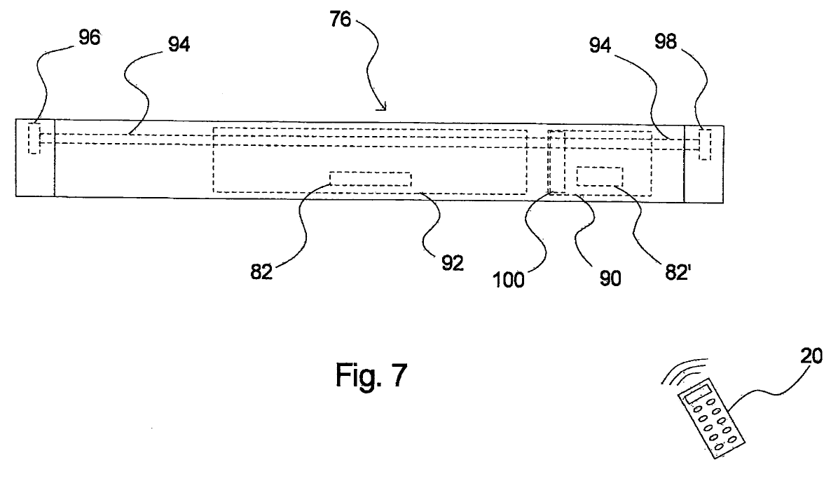

FIG. 7 shows a bottom roller 76 as described above from the front, i.e. in the same direction as in FIG. 6, and with important features of the operator system according to the invention illustrated. Thus, it is shown that the bottom roller comprises at least one power drive mechanism or operator 90, which may comprise one or more electric motors, preferably DC motors, driven by power from a power supply unit 92. This power supply unit will preferably be in the shape of a battery pack, which may comprise one or more rechargeable or non-rechargeable batteries. The operator or drive mechanism 90 may furthermore comprise a transmission mechanism, which may be integrated in the electric motor and whereby a driving force may be transferred to one or more drive shafts 94, which may, in turn, transfer the driving force to driving means 96 and 98, respectively. These driving means 96, 98 are placed at each end of the bottom roller 76 for cooperation with the rails 72 and 74, respectively. It is obvious that more than one operator or driving mechanism 90 may be placed in a bottom roller, for example, one at each end, the driving mechanisms being controllable in relation to each other, incl. being synchronized in relation to each other, but e.g. also in such a manner that rolling the screening up and down in non-rectangular windows, such as trapezoid or half-arched windows, may take place as well.

As previously mentioned, the control signals from, e.g., a remote control 20 is received by receiver or transceiver means 82 placed separately or by receiver or transceiver means 82 placed in connection with or integrated with the operator 90. As indicated and in accordance with the invention, a connection module 100 may also be placed in connection with or integrated with the operator 90. The control signals are sent to the operator or drive mechanism 90, comprising one or more electrical motors, e.g. DC motors and associated transmission mechanisms, gearings etc. The movement is then transferred via mechanical transmission means comprising drive shaft(s), drive means, incl. e.g. drive wheels 96, 98, and rails 72, 74 whereby the moving power is transferred and the e.g. screening device is unrolled or rolled up.

The power supply module 92, which may preferably comprise one or more batteries as already mentioned, e.g. in the form of a battery pack, supplies power to the operator, e.g. the drive mechanism/electrical motor 90, and this battery pack may comprise rechargeable or non-rechargeable batteries as explained above. When rechargeable batteries are used, charging means (not shown) may be provided, for example in the form of solar cell(s) located on the bottom roller housing or on e.g. the window in a suitable place. Electric power from e.g. solar cells may be transferred to the battery pack via charging circuit means. Electric power may be supplied to the battery pack by other suitable means, e.g. from a mains supply via a transformer and rectifier means, which may be particularly suitable when the operator is placed in a part which is fixed in relation to the window, for example when the operator is placed in a top box of a screening device. If the operator is placed in a part which is movable in relation to e.g., a window, a power supply system comprising solar cell(s) may be preferable. Alternatively, a power supply system comprising, e.g., electromagnetic power transferring, current collectors or other suitable means may be preferable.

A sensor module has not been illustrated in connection with the embodiment shown in FIGS. 6 and 7, but one or more sensors may be provided in accordance with the invention and as described above in connection with FIGS. 1 and 2. In particular, such sensors may, for example, be a daylight sensor and/or a temperature sensor, e.g. in order to perform an automatic or a semi-automatic closing and/or opening of a screening device, roller blinds etc. in dependence on incoming light, e.g. sunlight and/or the temperature e.g. inside a room.

From the above-mentioned, it will be seen that an aperture member, such as a window or a door, may be provided with an operating system and in particular a remote-controlled operating system at the manufacturing stage or subsequent to this stage, but before actual installation of the aperture member, e.g. the door or window.

All necessary components apart from the remote control and possibly a receiver module may be mounted in or on the frame of the aperture member or in or on means such as a screening device associated with the aperture member, all modifications to the e.g. window may be performed during manufacture and all parts may be delivered to the buyer and be ready for installation.

A buyer, e.g. a craftsman, a building contractor etc. will then have to install e.g. the window in an aperture, and connect the power supply cord to an electricity mains outlet, if the power supply is intended to come from such a supply. If it is purely battery operated, batteries need to be installed. Of course, batteries may also be installed if the system is intended for a battery back-up system, e.g. serving to keep the operator system operational in case of power failures.

Possibly, the remote control and the receiver or transceiver module will have to be adjusted to the same coding, e.g. in order to be able to communicate with each other.

This may be done by means of DIP-switches (not shown) provided on the receiver module and/or the remote control. Further, it may be necessary to change other coding means on the receiver module in order to set the receiver module to operate under special conditions, e.g. when cooperating with other operating systems, e.g. windows which may be operated simultaneously. The receiver module may then be inserted in the system, e.g. in a dedicated connection interface, and the system will be operational, possibly after having performed some test routines of the system in order to e.g. adjust the operating system for performance under the specific friction conditions etc.

Further, the remote control and the receiver or transceiver module may be configured without using DIP-switches etc., for example by using a configuration scheme involving special communication between the remote control and the receiver or transceiver module. By special operation of one or both of the units involved, e.g. by activation of certain keys or combinations of keys, codes, addresses etc. may be transferred and/or set and similarly other control parameters may be set, e.g. configuration of groups of windows that may be controlled by a certain command etc.

It should be noted that an operating system using a separate receiver or transceiver module may be advantageous in a system using e.g. infra red radiation signals for the remote control since the receiver module may be located in a place in which radiation will not be hindered in reaching the module under these circumstances, e.g. a “free line of sight” may be established between the remote control and the receiver or transceiver module.

When an operating system utilizes a receiver or transceiver module built into the operator or its housing, a remote control system utilizing for example radio frequency radiation signals may advantageously be used, e.g. a radiation system not demanding a “free line of sight” from the remote control to the receiver means.

The invention has been explained in the above with reference to specific embodiments. However, it will be understood that the invention may be modified in a number of ways, which will be obvious to a person skilled in the art, and that these are included in the scope of the invention defined by the claims.

For example, the operator system need not be controlled via a remote control but may be controlled via wired control means, e.g. control buttons or similar means placed in part of a window, or central or local control interfaces, for example placed in proximity to or even integrated with light switches, switching panels, etc. placed in e.g. a wall of a room. These wired control means may be wired to the operator system via wire from the window and may be connected to the operator system by, e.g., plug means.

Further, it will be understood that receiver means and control means described above may be designed as transceiver means, and that the communication between these means performed in any suitable manner, e.g. by electric signals, electromagnetic signals such as infrared signals or radio frequency signals etc.

It will also be understood that the use of the invention is not limited to the particular examples described above but may be used in connection with any type of member or means associated with an aperture member such as a window or a door in order to achieve an automatic or adjustable movement, variation, setting etc.

That which is claimed is:

1. A system for use with an aperture, including a fixed frame surrounding the aperture and a movable part that moves relative to the fixed frame and the aperture, the system comprising:
a power supply module including a storage unit to store power;
a receiver to receive a control signal from a controller;
a connection module by which power is supplied to the receiver from the power supply module; and
an operator, coupled to the connection module and receptive of power from the power supply module and the control signal from the receiver, including a drive unit that drives the movable part to move based on the control signal and a charging unit to charge the storage unit.

2. The system according to claim 1, wherein the charging unit operates independently from a power supply external from the system.

3. The system according to claim 1, wherein the charging unit comprises a solar cell.

4. The system according to claim 3, wherein the solar cell is disposed on the aperture in a sunlight receiving position.

5. The system according to claim 3, wherein the solar cell is disposed on the movable part.

6. The system according to claim 5, wherein the operator is at least partly disposed within the movable part.

7. The system according to claim 1, further comprising a sensor to sense a condition proximate to the aperture.

8. The system according to claim 7, wherein the sensor is mounted on at least one of the fixed frame and the movable part.

9. A system for use with an aperture, including a fixed frame surrounding the aperture and a movable part that moves relative to the fixed frame and the aperture, the system comprising:
a power supply module;
a receiver to receive a control signal from a controller;
a connection module by which power is supplied to the receiver from the power supply module; and
an operator, coupled to the connection module and receptive of power from the power supply module and the control signal from the receiver, including a drive unit that drives the movable part to move based on the control signal.

10. The system according to claim 9, wherein the connection module comprises a separate module placed separately from the operator.

11. The system according to claim 9, wherein the connection module comprises a separate module placed in connection with the operator.

12. The system according to claim 9, wherein the connection module is integrated with the operator.

13. A system for use with an aperture, including a fixed frame surrounding the aperture and a movable part that moves relative to the fixed frame and the aperture, the system comprising:
a power supply module;
a connection module; and
an operator, coupled to the connection module and receptive of power from the power supply module via the connection module, including a receiver to receive a control signal from a controller and a drive unit that drives the movable part to move based on the control signal.

14. The system according to claim 13, further comprising a connecting interface of the receiver which is separate from the operator.

15. A system for use with an aperture, including a fixed frame surrounding the aperture and a movable part that moves relative to the fixed frame and the aperture, the system comprising:
a power supply module;
a receiver to receive a control signal from a controller;
a connection module by which power is supplied to the receiver from the power supply module; and
an operator, coupled to the connection module and receptive of power from the power supply module and the control signal from the receiver, including an operator member having a fastener and end fasteners that cooperatively fasten the operator to the movable part and a drive unit that drives the movable part to move based on the control signal.

16. The system according to claim 15, wherein the fastener comprises a fork part to grip the end fasteners.

17. The system according to claim 15, wherein the operator member comprises a chain member including the end fasteners.

18. The system according to claim 15, wherein the fastener is configured to connect with a sash part of the movable part.

19. A system for use with an aperture, including a fixed frame surrounding the aperture and a movable part that moves relative to the fixed frame and the aperture, the system comprising:
a power supply module;
a receiver to receive a control signal from a controller, the receiver including an indicator to indicate that the control signal is received;
a connection module by which power is supplied to the receiver from the power supply module; and
an operator, coupled to the connection module and receptive of power from the power supply module and the control signal from the receiver, including a drive unit that drives the movable part to move based on the control signal.

20. The system according to claim 19, wherein the indicator comprises a light emitting diode (LED).

21. The system according to claim 19, wherein the indicator indicates that the control signal is received by flashing.

22. The system according to claim 19, wherein the indicator indicates that the control signal is received and that the operator is operating by emitting constant light.

23. A power supply system for an operator system for use with an aperture, including a fixed frame surrounding the aperture and a movable part that moves relative to the fixed frame and the aperture, the operator system comprising a power supply module including a storage unit to store power and an operator, including a drive unit that drives the movable part to move based on a received control signal and a charging unit to charge the storage unit.

24. The power supply system according to claim 23, wherein the charging unit operates independently from a power supply external from the operator system.

25. The power supply system according to claim 23, wherein the charging unit comprises a solar cell.

26. The power supply system according to claim 25, wherein the solar cell is disposed on the aperture in a sunlight receiving position.

27. The power supply system according to claim 25, wherein the solar cell is disposed on the movable part.

28. The power supply system according to claim 27, wherein the operator is at least partly disposed within the movable part.

29. An aperture system, comprising:
a fixed frame surrounding an aperture;
a movable part that moves relative to the fixed frame and the aperture;
a power supply module, disposed on one of the fixed frame and the movable part, including a storage unit to store power;
a receiver, disposed on one of the fixed frame and the movable part, to receive a control signal from a controller; and
an operator, disposed on or at least partly in one of the fixed frame and the movable part, receptive of power from the power supply module and the control signal from the receiver and including a drive unit that drives the movable part to move based on the control signal and a charging unit to charge the storage unit.

30. A system for use with an aperture, including a fixed frame surrounding the aperture and a movable part that moves relative to the fixed frame and the aperture, the system comprising:
a power supply module including a storage unit to store power;
a receiver to receive a control signal from a controller; and
an operator, receptive of power from the power supply module and the control signal from the receiver, including a drive unit that drives the movable part to move based on the control signal and a charging unit to charge the storage unit.
